(19) United States
(12) Patent Application Publication
(10) Pub. No.: US 2024/0427979 A1
(43) Pub. Date: Dec. 26, 2024

(54) SUBSTRATE STRESS UNIFORMITY MANAGEMENT BASED ON OVERLAY ERROR MEASUREMENTS

(71) Applicant: Applied Materials, Inc., Santa Clara, CA (US)

(72) Inventors: Zhiling Dun, Campbell, CA (US); Allison Yao, Mountain View, CA (US); Jingmin Leng, Santa Clara, CA (US); Xinhai Han, Palo Alto, CA (US); Deenesh Padhi, Sunnyvale, CA (US)

(21) Appl. No.: 18/752,132

(22) Filed: Jun. 24, 2024

Related U.S. Application Data
(60) Provisional application No. 63/523,328, filed on Jun. 26, 2023.

(51) Int. Cl. G06F 30/398

(52) U.S. Cl. CPC G06F 30/398

(57) ABSTRACT

A method includes obtaining, by a processing device, first data indicative of overlay error of a substrate. The method further includes generating second data indicative of first stress uniformity of the substrate based on the first data. The method further includes performing a corrective action based on the second data.

### RELATED APPLICATIONS

The present application claims the benefit of U.S. Provisional Patent Application No. 63/523,328, filed Jun. 26, 2023, entitled “SUBSTRATE STRESS MANAGEMENT BASED ON OVERLAY ERROR,” which is incorporated by reference herein.

### TECHNICAL FIELD

The present disclosure relates to substrate stress uniformity management for substrate generation procedures, and more specifically the present disclosure relates to substrate stress uniformity management based on overlay error for substrate generation procedures.

### BACKGROUND

Products may be produced by performing one or more manufacturing processes using manufacturing equipment. For example, semiconductor manufacturing equipment may be used to produce substrates via semiconductor manufacturing processes. Products are to be produced with particular properties, suited for a target application. Understanding and controlling properties within the manufacturing chamber aids in consistent production of products. Connections between substrate generation parameters and substrate properties may be exploited for design or improvement of substrate generation procedures. Performing processing operations alter the properties of substrates. Some properties of substrates are directly physical meaning and easier to control/optimize, e.g., stress of substrates, while some other properties are less physical meaning and more difficult to control, e.g., in-plane distortions.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular embodiments of the disclosure or any scope of the claims. Its sole purpose is to present some concepts of the disclosure in a simplified form as a prelude to the more detailed description that is presented later.

In one aspect of the present disclosure, a method includes obtaining, by a processing device, first data indicative of overlay error of a substrate. The method further includes generating second data indicative of first stress uniformity of the substrate based on the first data. The method further includes performing a corrective action based on the second data.

In another aspect of the present disclosure, a non-transitory machine-readable storage medium stores instructions which, when executed, cause a processing device to perform operations including obtaining first data indicative of overlay error of a substrate. The operations further include generating second data indicative of first stress uniformity of the substrate based on the first data. The operations further include performing a corrective action based on the second data.

In another aspect of the present disclosure, a system includes memory and a processing device coupled to the memory. The processing device is configured to obtain first data indicative of overlay error of a substrate. The processing device is further configured to generate second data indicative of stress of the substrate based on the first data. The processing device is further configured to perform a corrective action based on the second data.

### BRIEF DESCRIPTION OF THE DRAWINGS

The present disclosure is illustrated by way of example, and not by way of limitation in the figures of the accompanying drawings.

FIG. 1 is a block diagram illustrating an exemplary system architecture, according to some embodiments.

FIG. 2 depicts a flow for utilizing a stress calculation for substrate processing operations analysis, according to some embodiments.

FIG. 3 depicts in-plane distortion data and a corresponding stress map, according to some embodiments.

FIG. 4 is a flow diagram of a method for performing a corrective action based on stress data generated from overlay error data, according to some embodiments.

FIG. 5 is a block diagram illustrating a computer system, according to some embodiments.

### DETAILED DESCRIPTION

Described herein are technologies related to determining substrate stress based on overlay error, which may further be used in performance of corrective actions associated with substrate processing procedures. Manufacturing equipment may be used to produce products, such as substrates (e.g., wafers, semiconductors, displays, photovoltaics, etc.). Manufacturing equipment (e.g., manufacturing tools) often includes a processing chamber that separates the substrate being processed from an external environment. The properties of produced substrates are to meet target property values to facilitate performance, functionality, etc. Anomalies, drift, or other differences in processing environment may generate substrates with sub-optimal performance, e.g., semiconductors that fail to function as intended, inefficiencies in manufacturing (for example, additional expenditure of time, materials, energy, etc.), and so on. A processing environment may be quantified by various sensors associated with a processing chamber, e.g., pressure gauges, temperatures sensors, sensors indicative of electrical power (e.g., voltmeters, etc.), gas flow meters, etc.

Manufacturing of substrates may include various operations that alter properties of a substrate. For example, substrate manufacturing operations may include depositing one or more films on a surface of the substrate. Deposition of a film may induce change of stress in a substrate. Stress induced by a process operation may cause substrate bowing or warp, out-of-plane distortion, in-plane distortion, overlay error, etc.

Measurement and analysis of substrate distortion may be performed. For example, a vector map of in-plane distortions associated with a number of locations of a substrate may be generated, indicating magnitude and direction of in-plane distortion (e.g., overlay error) at the locations. Substrate distortions may be indicative of potential improvements that may be made to a substrate manufacturing procedure, e.g., to reduce manufacturing variations between substrates, to reduce variation in distortion across a substrate, etc.

In-plane distortion of a substrate may be measured, e.g., based on overlay error of features of different layers of a substrate. In-plane distortion measurements may be difficult or inconvenient to translate to root causes, to use for corrective actions, or the like. For example, in-plane distortions may include a map of two-dimensional vectors which may be inconvenient to interpret, inconvenient to provide as input to a model (e.g., a large number of inputs may be inconvenient for a physics-based or machine-learning model), etc. Methods for generating data that is easier to use in generating insights into a manufacturing process may have difficulties, such as complexity of data generation, challenges in finding correlations between simplified data and corrective actions, reduced usefulness of the simplified data, etc. Some methods of reducing dimensionality of in-plane distortion data may not be physically meaningful, may not be indicative of root causes of manufacturing issues, or the like.

Methods and systems of the present disclosure may address one or more shortcomings of conventional methods. In some embodiments, data corresponding to in-plane distortion or overlay error of a substrate is generated. The data may include a vector map, indicating magnitude and direction of in-plane distortion of various regions of the substrate. A mathematical transformation may be applied to the in-plane distortion data to generate a stress map of the substrate. Generating the stress map may include calculating the divergence of the in-plane distortion.

In some embodiments, the divergence of the in-plane distortion is correlated to the stress of the substrate. The stress may be related to one or more films deposited on the substrate. The stress may be induced by depositing one or more films on the substrate. A stress map of the substrate may have one or more advantages over a conventional analysis method.

Stress of the substrate is physically meaningful. By providing data indicative of a map of substrate stress, corrective actions may be recommended and/or performed to adjust stresses induced by film deposition in substrates. For example, target stress profiles for achieving target substrate properties may be achieved by adjusting one or more parameters related to substrate manufacturing in view of substrate stress data.

In some embodiments, further insights may be achieved by further processing of the stress data. For example, stress data may be decomposed. As a first example, a polynomial fit of stress data may be generated. Various orders of the fit (e.g., a zeroth order term, first order term, second order term, etc.) may be associated with higher-order wafer alignment (HOWA) of overlay errors, indicative of respective root causes of manufacturing faults, associated corrective actions, or the like. Stress data may be decomposed into planar, radial, and residual parts, which may each be indicative of one or more root causes of manufacturing faults, corrective actions, or the like.

In some embodiments, stress related to multiple types of films may be calculated. For example, properties of films of various materials (e.g., oxide films, nitride films, etc.) may be understood by generating stress data associated with films of the materials. Stress variations of a target stacked substrate may be predicted from stress maps indicative of properties of types of films included in the target substrate.

In some embodiments, one or more corrective actions may be performed based on stress map data of substrates. Corrective actions may include providing a stress map for a user. Corrective actions may include providing a decomposed stress map for a user. Corrective actions may include providing an alert to a user. For example, an alert indicating that a stress profile does not satisfy one or more threshold criteria, an alert that a stress profile includes variations outside a threshold, or something unexpected presented in the substrates (e.g., arcing of the wafer, local spotting of the plasma density during deposition, or the like). Corrective actions may include updating a process recipe. For example, adjustment to a deposition operation (e.g., adjusting gas flow, temperature, processing time, etc.) may be performed to improve a stress profile of a substrate. Corrective actions may include recommending or performing maintenance (e.g., a large planar component of the stress map indicates some leveling of the system is required). Corrective actions may include recommending a change of components of a processing system

Methods and systems of the present disclosure provide technological advantages over conventional solutions. Generating a stress map conventionally may include performing additional difficult, time-consuming, and/or expensive measurement techniques. Generating a stress map from overlay error data may provide the benefits of a complicated substrate stress measurement without the difficulties of performing the measurement. Generating a stress map from overlay error data may provide benefits of a substrate stress measurement using calculations based on a previously performed overlay or in-plane distortion measurement. Performing corrective actions based on stress data may be more likely to improve a manufacturing process than performing corrective actions based on in-plane distortion data. Performing corrective actions based on stress data generated from overlay error data may be performed without an expensive substrate stress measurement, which may increase throughput, decrease cost of substrate production, or the like.

In one aspect of the present disclosure, a method includes obtaining, by a processing device, first data indicative of overlay error of a substrate. The method further includes generating second data indicative of first stress uniformity of the substrate based on the first data. The method further includes performing a corrective action based on the second data.

In another aspect of the present disclosure, a non-transitory machine-readable storage medium stores instructions which, when executed, cause a processing device to perform operations including obtaining first data indicative of overlay error of a substrate. The operations further include generating second data indicative of first stress uniformity of the substrate based on the first data. The operations further include performing a corrective action based on the second data.

In another aspect of the present disclosure, a system includes memory and a processing device coupled to the memory. The processing device is configured to obtain first data indicative of overlay error of a substrate. The processing device is further configured to generate second data indicative of stress of the substrate based on the first data. The processing device is further configured to perform a corrective action based on the second data.

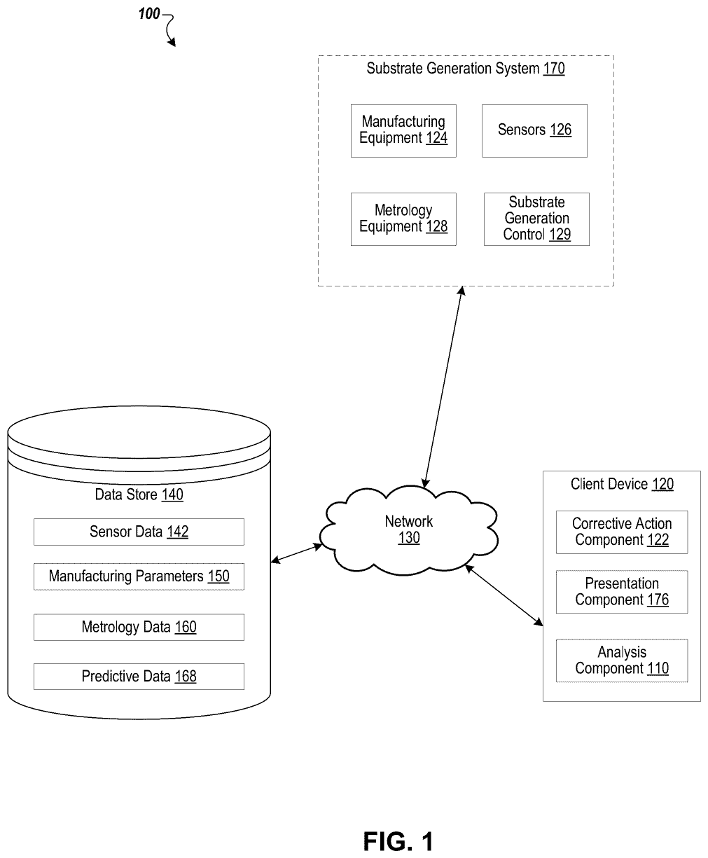

FIG. 1 is a block diagram illustrating an exemplary system 100 (e.g., exemplary system architecture), according to some embodiments. System 100 includes a client device 120, substrate generation system 170, and a data store 140.

Substrate generation system 170 includes components for performing operations for substrate generation, substrate property data generation, numeric data generation, etc. Substrate generation system 170 includes manufacturing equipment 124, sensors 126, metrology equipment 128, and substrate generation control 129. Substrate generation control 129 may include one or more processing devices, memory devices, etc., configured to perform operations associated with substrate generation system 170, such as providing control for manufacturing equipment 124, sensors 126, metrology equipment 128, etc. Substrate generation control 129 may include one or more computing devices such as Personal Computers (PCs), laptops, mobile phones, smart phones, tablet computers, netbook computers, network connected televisions (“smart TV”), network-connected media players (e.g., Blu-ray player), a set-top-box, Over-the-Top (OTT) streaming devices, operator boxes, etc.

Manufacturing equipment 124 may include one or more process tools, process chambers, process equipment, etc., for producing physical substrates. Manufacturing equipment may be provided with and execute instructions for processing substrates, such as semiconductor wafers. Manufacturing equipment may be provided with instructions for processing substrates in the form of process recipes. Process recipes may provide instructions for carrying out process procedures, which may include one or more process operations.

Substrate generation system 170 includes sensors 126. Sensors 126 may provide sensor data 142 associated with manufacturing equipment 124 (e.g., associated with producing, by manufacturing equipment 124, corresponding products, such as substrates). Sensor data 142 may be used for ascertaining equipment health and/or product health (e.g., product quality). Manufacturing equipment 124 may produce products following a recipe or performing runs over a period of time. In some embodiments, sensor data 142 may include values of one or more of temperature (e.g., heater temperature), spacing (SP), pressure, High Frequency Radio Frequency (HFRF), radio frequency (RF) match voltage, RF match current, RF match capacitor position, voltage of Electrostatic Chuck (ESC), actuator position, electrical current, flow, power, voltage, etc.

Sensor data 142 may be associated with or indicative of manufacturing parameters such as hardware parameters (e.g., settings or components, e.g., size, type, etc.) of manufacturing equipment 124 or process parameters of manufacturing equipment 124. Data associated with some hardware parameters may, instead or additionally, be stored as manufacturing parameters 150. Manufacturing parameters 150 may be indicative of input settings to the manufacturing device (e.g., heater power, gas flow, etc.). Sensor data 142 and/or manufacturing parameters 150 may be provided while manufacturing equipment 124 is performing manufacturing processes (e.g., may be equipment readings generated during processing of substrates). Sensor data 142 may be different for each product (e.g., each substrate). Substrates may have property values (e.g., film thickness, film strain, etc.) measured by metrology equipment 128. Metrology data 160 may be a type of data stored in data store 140.

Substrate generation system 170 includes metrology equipment 128. Metrology equipment 128 measures one or more properties of substrates and provides metrology data 160 based on the measurements. Metrology data 160 may include measurements of substrate distortion in embodiments. Metrology equipment 128 may include equipment configured to measure substrate distortion. Metrology equipment 128 may include equipment configured to determine in-plane distortion and/or overlay error of a substrate.

In-plane distortion may include a measure of warpage of a substrate. Excessive in-plane distortion may lead to issues during fabrication processes such as photolithography and wafer bonding. In-plane distortion may be measured, for example, via interferometry, while light scanning interferometry, laser scanning, and so on. Interferometry involves directing a beam of monochromatic light (often from a laser) at a substrate and then analyzing the interference pattern created when this light combines with a reference beam. Distortions or misalignments between films of a substrate may be determined based on the interference pattern.

Metrology equipment 128 may include scatterometry-based overlay error measurement tools. Overlay error may include a misalignment of pattern layers on a substrate. With modern integrated circuits having many layers, a precise alignment of the multiple layers can be both difficult to achieve and vital for substrate performance. Scatterometry techniques take advantage of light scattering from periodic structures, similar to scattering from a diffraction grating. Intensities of various scattered components, such as various diffraction orders, may be used to determine differences in position of structures of various layers of a film. The difference in position, or displacement, may provide the overlay error.

Metrology equipment 128 may include one or more imaging-based overlay error measurement tools. Metrology equipment 128 may include one or more interference-pattern based overlay error measurement tools, or any other tool for measuring in-plane distortion of a substrate, overlay error of a substrate, etc. Data store 140 may store overlay error data as metrology data 160. Data store 140 may store overlay error data as vector maps indicating direction and magnitude of in-plane distortion at a number of locations of the substrate.

In some embodiments, sensor data 142, metrology data 160, and/or manufacturing parameters 150 may be processed (e.g., by the client device 120). Processing of sensor data 142, metrology data 160, and/or manufacturing parameters 150 may include generating features. In some embodiments, the features are a pattern in the sensor data 142, metrology data 160, and/or manufacturing parameters 150 (e.g., slope, width, height, peak, etc.) or a combination of values from the sensor data 142, metrology data 160, and/or manufacturing parameters 150 (e.g., power derived from voltage and current, etc.). Sensor data 142 may include features and the features may be used by client device 120 for performing signal processing and/or for obtaining predictive data 168 for performance of a corrective action.

Each instance (e.g., set) of sensor data 142 may correspond to a product (e.g., a substrate), a set of manufacturing equipment, a type of substrate produced by manufacturing equipment, a substrate generation recipe, or the like. Each instance of metrology data 160 and manufacturing parameters 150 may likewise correspond to a product, a set of manufacturing equipment, a type of substrate produced by manufacturing equipment, or the like. Data store 140 may further store information associating sets of different data types, e.g. information indicative that a set of sensor data, a set of metrology data, and a set of manufacturing parameters are all associated with the same product, manufacturing equipment, type of substrate, etc.

Client device 120, components of substrate generation system 170, and data store 140 may be coupled to each other via network 130 for generating predictive data 168 to perform corrective actions.

Client device 120 includes corrective action component 122, presentation component 176, and analysis component 110. Client device 120 may perform various operations for substrate classification, predictive data generation, corrective action performance, etc. Client device 120 may receive data indicative of properties of one or more substrates. Client device 120 may receive data from metrology equipment 128, data store 140, etc. Client device 120 may perform operations for generating predictive data 168 and/or recommending or performing corrective actions.

Presentation component 176 of client device 120 may present a user interface (UI). The UI may include one or more UI elements. The UI may present data associated with performance and/or properties of one or more substrates. Substrate data presented may include numeric data. Substrate data presented may include non-numeric data, such as plots, charts, diagrams, etc.

In some embodiments, sensor data 142, metrology data 160, and/or manufacturing parameters 150 may be processed (e.g., by the client device 120). Processing of sensor data 142, metrology data 160, and/or manufacturing parameters 150 may include generating features. In some embodiments, the features are a pattern in the sensor data 142, metrology data 160, and/or manufacturing parameters 150 (e.g., slope, width, height, peak, etc.) or a combination of values from the sensor data 142, metrology data 160, and/or manufacturing parameters 150 (e.g., power derived from voltage and current, etc.).

In some embodiments, analysis component 110 of client device 120 may generate predictive data 168. Predictive data 168 may be indicative of a corrective action (which may be performed by corrective action component 122, for example). Analysis component 110 may generate predictive data 168 based on metrology data provided by metrology equipment 128. Analysis component 110 may perform analysis based on correlations between substrate generation parameters (e.g., manufacturing parameters 150) and substrate properties (e.g., as represented by metrology data 160). Analysis component 110 may perform one or more calculations to generate predictive data 168.

Analysis component 110 may perform calculations on data indicative of in-plane distortion of a substrate. Analysis component 110 may perform calculations on data indicative of overlay error of a substrate. Analysis component 110 may predict substrate stress based on in-plane distortion data (e.g., overlay error data). Analysis component 110 may generate a substrate stress map based on a vector field indicative of in-plane distortion. Analysis component 110 may perform a divergence calculation to determine stress from in-plane distortion measurements. Predictive data 168 may include stress maps calculated based on overlay error data.

In some embodiments, analysis component 110 may generate predictive data 168 utilizing a statistical model, such as a regression model, principle component analysis model, machine learning model, etc. In some embodiments, analysis component 110 may perform a fit based on substrate generation parameters and substrate performance (e.g., metrology data 160).

In some embodiments, analysis component 110 may generate predictive data 168 using machine learning, such as supervised machine learning (e.g., a machine learning model may be configured to produce labels associated with input data, such as metrology predictions, performance predictions, etc.). In some embodiments, analysis component 110 may generate predictive data 168 using unsupervised machine learning (e.g., a machine learning model may be trained with unlabeled data, such as a model configured to perform clustering, dimensional reduction, etc.). In some embodiments, analysis component 110 may generate predictive data 168 using semi-supervised learning (e.g., a machine learning model may be trained using both labeled and unlabeled input data sets).

In some embodiments, network 130 is a public network that provides client device 120 with access to the data store 140, components of substrate generation system 170, and other publicly available computing devices. In some embodiments, network 130 is a private network that provides client device 120 access to manufacturing equipment 124, sensors 126, metrology equipment 128, data store 140, and other privately available computing devices. In some embodiments, the functions of one or more of client device 120 and/or analysis server 112 may be performed by a virtual machine, e.g., utilizing a cloud-based service. Network 130 may provide access to such virtual machines. Network 130 may include one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

Client device 120 may include a computing device such as Personal Computers (PCs), laptops, mobile phones, smart phones, tablet computers, netbook computers, network connected televisions (“smart TV”), network-connected media players (e.g., Blu-ray player), a set-top-box, Over-the-Top (OTT) streaming devices, operator boxes, etc. The client device 120 may include a corrective action component 122. Corrective action component 122 may receive user input (e.g., via a Graphical User Interface (GUI) displayed via the client device 120) of an indication associated with system 100.

In some embodiments, corrective action component 122 transmits an indication of a corrective action to substrate generation system 170, and causes the corrective action to be implemented. Causing the corrective action to be implemented may include updating one or more substrate generation operations, such as updating process recipes, updating simulation models, etc. Corrective action component 122 may implement one or more corrective actions, such as providing an alert to a user, recommending a modification or update to a process, recommending and/or scheduling maintenance, etc.

In some embodiments, metrology data 160 corresponds to historical property data of products. Predictive data 168 may include analysis results, e.g., output of analysis component 110, stress maps generated based on overlay error data and/or in-plane distortion data, predicted system failure, corrective actions to be performed, maintenance to be performed, etc. In some embodiments, predictive data 168 is an indication of abnormalities (e.g., abnormal products, abnormal components, abnormal manufacturing equipment 124, abnormal energy usage, etc.) and optionally one or more causes of the abnormalities. In some embodiments, predictive data 168 is an indication of change over time or drift in some component of manufacturing equipment 124, sensors 126, metrology equipment 128, and the like. In some embodiments, predictive data 168 is an indication of an end of life of a component of manufacturing equipment 124, sensors 126, metrology equipment 128, or the like.

Performing manufacturing processes that result in defective products can be costly in time, energy, products, components, manufacturing equipment 124, the cost of identifying the defects and discarding the defective product, etc. By providing data indicative of overlay error to a processing device, generating substrate stress data, and performing a corrective action based on the stress data, system 100 may reduce a likelihood of manufacturing equipment 124 producing defective products. For example, updating a process recipe or scheduling replacement of a failing component may reduce increase a likelihood of generating substrates by manufacturing equipment 124 that satisfy threshold performance metrics. System 100 can have the technical advantage of avoiding the cost of producing, identifying, and discarding defective products.

Manufacturing parameters may be sub-optimal for producing product, which may have costly results of increased resource (e.g., energy, coolant, gases, etc.) consumption, increased amount of time to produce the products, increased component failure, increased amounts of defective products, etc. By providing data indicative of overlay error to a processing device, generating substrate stress data, and performing a corrective action based on the stress data, system 100 can have the technical advantage of using optimal manufacturing parameters (e.g., hardware parameters, process parameters, optimal design) and/or healthy equipment to avoid costly results of sub-optimal manufacturing parameters.

Performing manufacturing processes that result in failure of the components of the manufacturing equipment 124 can be costly in downtime, damage to products, damage to equipment, express ordering replacement components, etc. By providing data indicative of overlay error to a processing device, generating substrate stress data, and performing a corrective action based on the stress data, system 100 can have the technical advantage of avoiding the cost of one or more of unexpected component failure, unscheduled downtime, productivity loss, unexpected equipment failure, product scrap, or the like. Monitoring the performance over time of components, e.g. manufacturing equipment 124, sensors 126, metrology equipment 128, and the like, may provide indications of degrading components.

Manufacturing processes may have an environmental impact. Manufacturing parameters may be less than optimal for reducing an environmental impact of manufacturing processes. By providing data indicative of overlay error to a processing device, generating substrate stress data, and performing a corrective action based on the stress data, system 100 may have the technical advantage of adjusting one or more manufacturing processes for reducing an environmental impact of manufacturing processes.

In some embodiments, the corrective action includes providing an alert. An alert may include an alarm to stop or not perform the manufacturing process on additional substrates if the predictive data 168 indicates a predicted abnormality, such as an abnormality of the product, a component, or manufacturing equipment 124, for example. In some embodiments, the corrective action includes providing feedback control (e.g., modifying a manufacturing parameter responsive to the predictive data 168 indicating a predicted abnormality). In some embodiments, performance of the corrective action includes causing updates to one or more manufacturing parameters.

Manufacturing parameters may include hardware parameters. Hardware parameters may include information indicating components included in the manufacturing equipment, indications of recently replaced components, indications of firmware versions or updates, etc. Manufacturing parameters may include process parameters. Process parameters may include set points for temperature, pressure, flow rate, electrical current and/or voltage, gas flow, lift speed, etc. In some embodiments, the corrective action includes causing preventative operative maintenance. Preventative operative maintenance may include instructions to replace, process, clean, etc. components of the manufacturing equipment 124. In some embodiments, the corrective action includes causing design optimization. Design optimization may include updating manufacturing parameters, updating manufacturing processes, updating manufacturing equipment 124, etc. for an optimized product or process. In some embodiments, the corrective action includes updating a recipe. Updating a recipe may include altering timing of instructions for manufacturing equipment 124 to be in an idle mode, a sleep mode, a warm-up mode, etc., adjusting set points for temperature, gas flow, plasma generation, etc.

Data store 140 may be a memory (e.g., random access memory), a drive (e.g., a hard drive, a flash drive), a database system, or another type of component or device capable of storing data. Data store 140 may include multiple storage components (e.g., multiple drives or multiple databases) that may span multiple computing devices (e.g., multiple server computers). The data store 140 may store sensor data 142, manufacturing parameters 150, metrology data 160, and predictive data 168. Data store 140 may be or include a cloud-based data storage device, a virtual data storage device, or the like.

In some embodiments, the functions of client device 120 and substrate generation system 170 may be provided by a fewer number of machines. For example, in some embodiments, client device 120 and one or more devices included in substrate generation control 129 may be integrated into a single machine.

In general, functions described in one embodiment as being performed by client device 120 or substrate generation control 129 can also be performed by the other of the two components in other embodiments, if appropriate. In addition, the functionality attributed to a particular component can be performed by different or multiple components operating together. For example, in some embodiments, devices that execute operations of substrate generation system 170 may determine the corrective action based on the predictive data 168. In another example, client device 120 may determine the predictive data 168 based on output from substrate generation system 170, etc.

In addition, the functions of a particular component can be performed by different or multiple components operating together. For example, operations of client device 120 may be accessed as a service provided to other systems or devices through appropriate application programming interfaces (API).

In embodiments, a “user” may be represented as a single individual. However, other embodiments of the disclosure encompass a “user” being an entity controlled by a plurality of users and/or an automated source. For example, a set of individual users federated as a group of administrators may be considered a “user.”

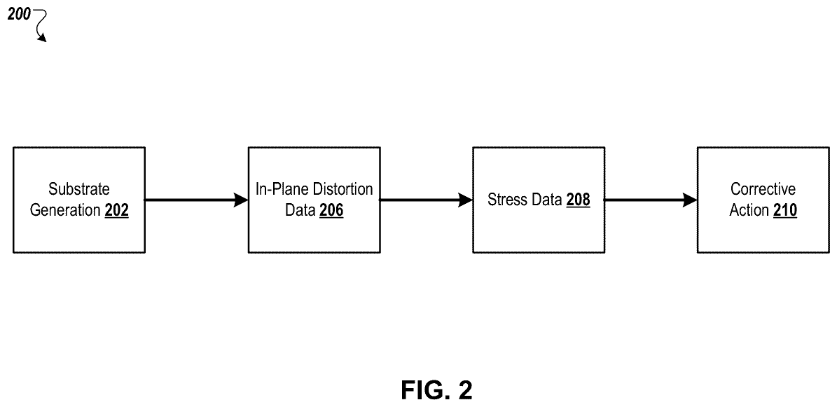

FIG. 2 depicts a flow 200 for utilizing a stress calculation for substrate processing operation analysis, according to some embodiments. Substrate generation 202 includes operations directed at generating one or more substrates. Generating physical substrates may include providing manufacturing parameters to manufacturing equipment, processing equipment, one or more process tools, etc. Generating physical substrates may include performing processing operations on substrate material to generate a manufactured substrate.

Property data associated with the one or more substrates may be generated. In-plane distortion data 206 may be generated by metrology equipment, such as metrology equipment 128 of FIG. 1. In-plane distortion data 206 may be indicative of film-induced distortions, stress-induced distortions, overlay errors, or the like. In-plane distortion data 206 may be related to stress-induced distortions of the substrate. For example, in depositing a film on the substrate, some changes to substrate shape may be induced due to stress associated with the deposited film. Structures, patterns, or the like of various layers of the substrate may be aligned in a way that is different than a target alignment. This difference in alignment between different layers may be measured as overlay error. The overlay error may be represented by a two-dimensional vector field, where each vector of the field indicates a magnitude and direction of the overlay error for the associated location of the substrate.

Stress data 208 may be generated based on in-plane distortion data 206. Stress data 208 may be generated by a processing device. Stress data 208 may be generated by performing one or more operations on in-plane distortion data 206. Stress data 208 may be generated by performing a divergence calculation on in-plane distortion data 206.

In vector calculus, divergence is a fundamental operation that measures the “spreading out” or “source/sink” behavior of a vector field. It is typically denoted by the symbol ∇. F, where ∇ (del) represents the nabla operator and · (dot) denotes the dot product.

Mathematically, the divergence of a vector field F=(F₁, F₂, F₃) in three-dimensional space is given by the following expression:

$$∇ \cdot F = ( \partial {F}_{1} / \partial x ) + ( \partial {F}_{2} / \partial y ) + ( \partial {F}_{3} / \partial z ) ,$$

where ∂F₁/∂x, ∂F₂/∂y, and ∂F₃/∂z represent the partial derivatives of the components of F with respect to the coordinates x, y, and z, respectively. In some embodiments, the vector field may be indicative of overlay error. The vector field may be limited to in-plane components, e.g., components in the (x,y) plane, in some embodiments. The divergence calculation may further include derivatives in the (x,y) plane. The divergence operations convert a vector field (e.g., a two-dimensional output indicating magnitude and direction of overlay error associated with a two-dimensional input space corresponding to the surface of a substrate) into a scalar field (e.g., a single output associated with each point of the two-dimensional input space corresponding to the surface of the substrate).

Stress data 208 is utilized in performing a corrective action 210, e.g., by corrective action component 122 of FIG. 1. Stress data 208 may be indicative of root causes of faults of manufacturing equipment. Stress data 208 may be indicative of appropriate corrective actions to perform in association with manufacturing equipment. Corrective actions may include providing an alert to a user (e.g., via a graphical user interface), updating a process recipe, recommending maintenance, performing maintenance, recommending a change of components of a manufacturing system, etc. For example, a target stress profile may be more closely aligned with a different piece of equipment than currently in use, such as a different gas delivery component or different substrate support.

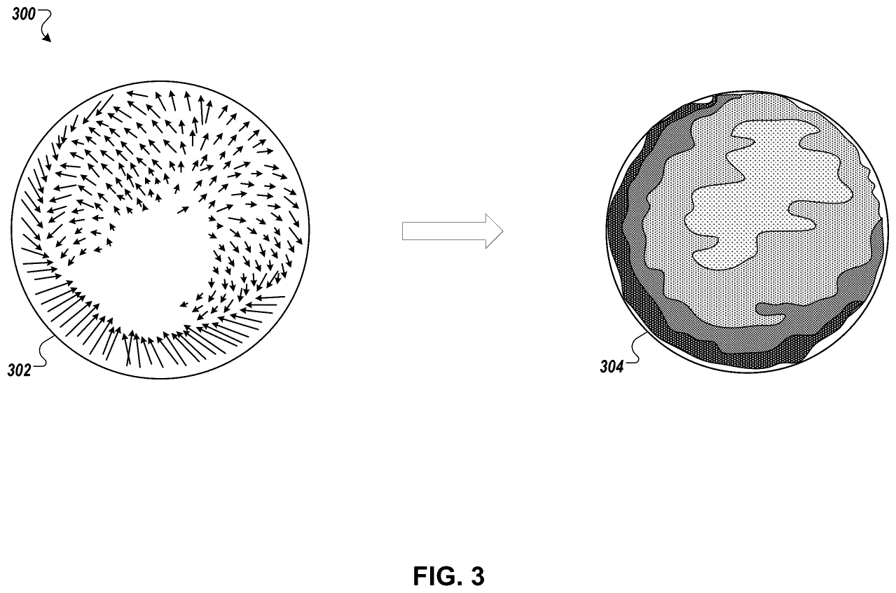

FIG. 3 depicts in-plane distortion data 302 and a corresponding stress map 304, according to some embodiments. Processing logic (e.g., of client device 120 of FIG. 1) may receive data indicative of in-plane distortion of a substrate. The data may be provided by metrology equipment. The data may indicate a magnitude and direction of overlay error of a number of locations of the substrate. One representation of such in-plane distortion data is a vector map, as shown as in-plane distortion data 302. Each arrow depicted in in-plane distortion data 302 represents a vector. The vectors represent the magnitude and direction of overlay error at a particular location of the substrate. In-plane distortion data 302 may be a vector map representing overlay error of the substrate.

Processing logic may generate stress map 304 based on in-plane distortion data 302. Generating stress map 304 may include generating one-dimensional output based on the two-dimensional vector map of in-plane distortion data 302. Generating stress map 304 may include performing a divergence calculation on the vector map represented in in-plane distortion data 302.

A stress map (e.g., stress map 304) may indicate a one dimensional (e.g., scalar) output based on a two dimensional input (e.g., two dimensional coordinates of locations of the substrate). Stress map 304 indicates different regions of relative high or low substrate stress based on patterning. Other schemes for a stress map 304 are possible, such as contour lines, a surface plot, a heat map, etc. Stress map 304 may be a visualization of results of a divergence calculation performed based on in-plane distortion data 302. Stress map 304 (and/or the underlying data comprising stress map 304) may be utilized in performing one or more corrective actions in association with substrate processing equipment.

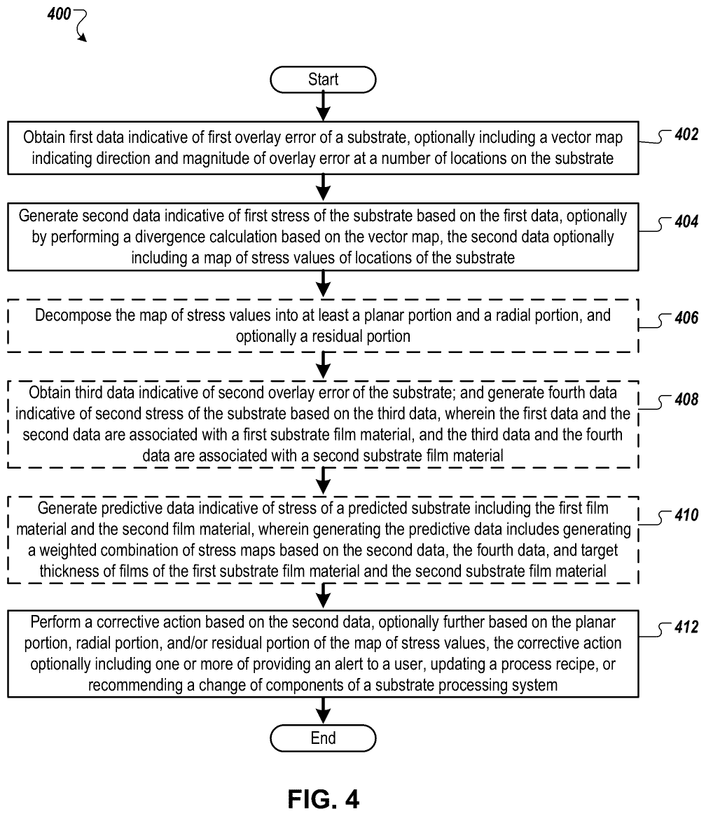

FIG. 4 is a flow diagram of a method 400 for performing a corrective action based on stress data generated from overlay error data, according to some embodiments. Method 400 may be performed by processing logic that may include hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiments, method 400 may be performed, at least in part, by client device 120, e.g., corrective action component 122, analysis component 110, etc. In some embodiments, a non-transitory machine-readable storage medium stores instructions that when executed by a processing device cause the processing device to perform operations of method 400.

For simplicity of explanation, method 400 is depicted and described as a series of operations. However, operations in accordance with this disclosure can occur in various orders and/or concurrently and with other operations not presented and described herein. Furthermore, not all illustrated operations may be performed to implement method 400 in accordance with the disclosed subject matter. In addition, those skilled in the art will understand and appreciate that method 400 could alternatively be represented as a series of interrelated states via a state diagram or events.

At block 402, processing logic obtains first data indicative of first overlay error of a substrate. The first data may be obtained from a metrology system measuring properties of the substrate, e.g., an in-plane distortion measurement tool. The first data may be or comprise a vector map. The vector map may indicate magnitude and direction of overlay error at a plurality of locations of the substrate.

In some embodiments, the first data may be related to deposition of a film of a first type. For example, the first data may be related to in-plane distortion of the substrate related to deposition of a first substrate film material. Further data may also be received related to a second type of film. For example, further in-plane distortion data associated with further substrate film materials may be measured by a metrology tool, obtained by processing logic, etc. Further operations of method 400 may be performed on additional data associated with additional types of films, additional sources of overlay error, etc.

At block 404, processing logic generates second data indicative of first stress of the substrates based on the first data. Generating the second data may include performing a divergence calculation based on the vector map. The second data may be a map of stress values associated with each of a plurality of locations of the substrate. Further divergence calculations may be performed on further overlay error data, e.g., for different types or materials of films. In some embodiments, predictive data associated with substrate stress may be generated. For example, stress data of one or more types of films may be used to predict stress of a multi-layered substrate, e.g., by performing a weighted combination of stress map data based on target film materials and thicknesses. Predictive data indicative of stress of a predicted substrate may be generated based on target film properties (e.g., material, thickness, etc.) of the predicted substrate.

In some embodiments, second data may be decomposed for further analysis. For example, at block 406, a stress map may be decomposed. The stress map may be fit in a polynomial fit, for example. In a further example, the stress map may be decomposed into physically meaningful portions, such as a linear, radial, and residual portion. As an example, the stress map may be decomposed into a first stress map that follows a linear change in stress across a substrate (e.g., a planar portion), a second stress map that includes changes in stress across the substrate as a function of radius (e.g., a radial portion), and a third stress map including stress not included in the other stress maps (e.g., a residual portion).

At block 408, second overlay error of the substrate is optionally utilized for further analysis. Processing logic optionally obtains third data, indicative of second overlay error of the substrate. The third data may share one or more features with the first data. Processing logic further generates fourth data based on the third data, the fourth data indicative of second stress of the substrate. The fourth data may share one or more features with the second data. The first and second data may be associated with a first type of film, a first film material, a first deposition technique, or the like. The second and third data may be associated with a second type of film, second film material, second deposition technique, etc.

At block 410, processing logic optionally generates predictive data indicative of stress of a predicted substrate including a first film and a second film, e.g., a first film material and second film material, first film type and second film type, film deposited by a first technique and second technique, or the like. Generating the predictive data may include generating a weighted combination of stress maps based on the second data, the fourth data, and target thicknesses of films (e.g., cumulative thicknesses of alternating layers) of the first substrate film and the second substrate film.

At block 412, processing logic performs a corrective action based on the second data. The corrective action may include providing an alert to a user, such as displaying representations of substrate stress and/or overlay error, for example in a similar manner to data presentation of FIG. 3. The corrective action may include updating a process recipe. The corrective action may include recommending and/or performing maintenance. The corrective action may include recommending a change of one or more components of a substrate processing system. For example, a different shape or design of gas delivery components or other processing system components may be recommended to adjust a stress profile of a substrate.

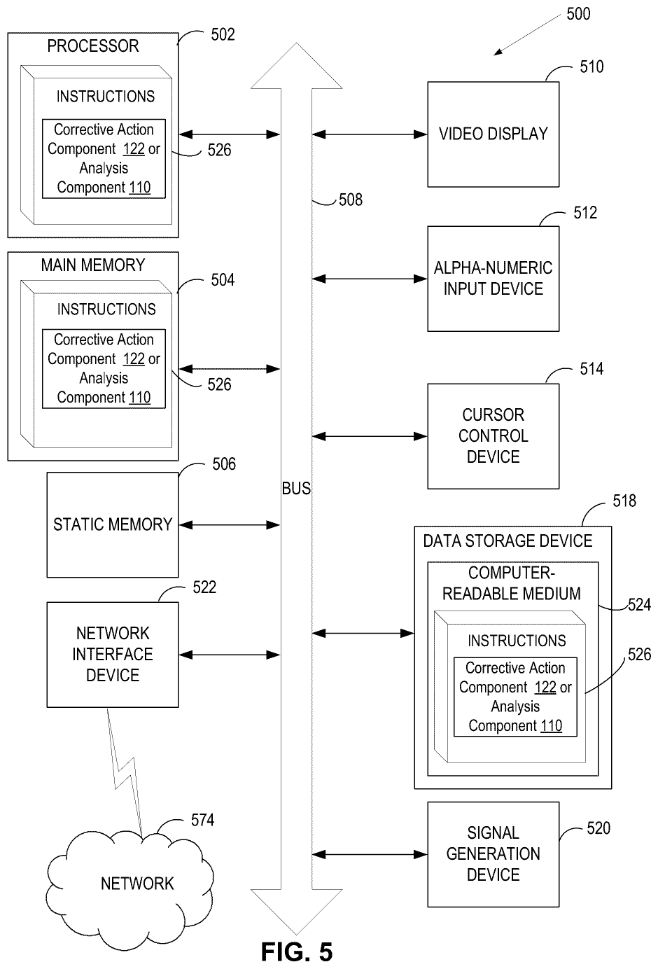

FIG. 5 is a block diagram illustrating a computer system 500, according to some embodiments. In some embodiments, computer system 500 may be connected (e.g., via a network, such as a Local Area Network (LAN), an intranet, an extranet, or the Internet) to other computer systems. Computer system 500 may operate in the capacity of a server or a client computer in a client-server environment, or as a peer computer in a peer-to-peer or distributed network environment. Computer system 500 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 500 may include a processing device 502, a volatile memory 504 (e.g., Random Access Memory (RAM)), a non-volatile memory 506 (e.g., Read-Only Memory (ROM) or Electrically-Erasable Programmable ROM (EEPROM)), and a data storage device 518, which may communicate with each other via a bus 508.

Processing device 502 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 500 may further include a network interface device 522 (e.g., coupled to network 574). Computer system 500 also may include a video display unit 510 (e.g., an LCD), an alphanumeric input device 512 (e.g., a keyboard), a cursor control device 514 (e.g., a mouse), and a signal generation device 520 (e.g., a speaker).

In some embodiments, data storage device 518 may include a non-transitory computer-readable storage medium 524 (e.g., non-transitory machine-readable medium) on which may store instructions 526 encoding any one or more of the methods or functions described herein, including instructions encoding components of FIG. 1 (e.g., analysis component 110, corrective action component 122, etc.) and for implementing methods described herein. Instruction 526 may encode functions performed by additional components, including presentation component 176, substrate generation control 129, etc.

Instructions 526 may also reside, completely or partially, within volatile memory 504 and/or within processing device 502 during execution thereof by computer system 500, hence, volatile memory 504 and processing device 502 may also constitute machine-readable storage media.

While computer-readable storage medium 524 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “receiving,” “performing,” “providing,” “obtaining,” “causing,” “determining,” “using,” “training,” “generating,” “correcting,” “updating,” “scheduling,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and embodiments, it will be recognized that the present disclosure is not limited to the examples and embodiments described. The scope of the disclosure should be determined with reference to the following claims, along with the full scope of equivalents to which the claims are entitled.

What is claimed is:

1. A method, comprising:
obtaining, by a processing device, first data indicative of first overlay error of a substrate;
generating second data indicative of first stress uniformity of the substrate based on the first data; and
performing a corrective action based on the second data.

2. The method of claim 1, wherein the first data comprises a vector map indicating direction and magnitude of overlay error at a plurality of locations of the substrate.

3. The method of claim 2, wherein generating second data indicative of stress of the substrate comprises performing a divergence calculation based on the vector map.

4. The method of claim 1, wherein the second data comprises a map of stress values associated with each of a plurality of locations of the substrate.

5. The method of claim 4, further comprising decomposing the map of stress values into at least a planar portion and a radial portion, and wherein the corrective action is further based on the planar portion or the radial portion.

6. The method of claim 1, further comprising:
obtaining third data indicative of second overlay error of the substrate; and
generating fourth data indicative of second stress of the substrate based on the third data, wherein the first data and second data are associated with a first substrate film material, and the third and fourth data are associated with a second substrate film material, different than the first.

7. The method of claim 6, further comprising generating predictive data indicative of stress of a predicted substrate comprising the first substrate film material and the second substrate film material, wherein generating the predictive data comprises generating a weighted combination of stress maps based on the second data, the fourth data, and target thicknesses of films of the first substrate film material and the second substrate film material.

8. The method of claim 1, wherein the corrective action comprises one or more of:
providing an alert to a user;
updating a process recipe; or
recommending a change of components of a substrate processing system.

9. A non-transitory machine-readable storage medium, storing instruction which, when executed, cause a processing device to perform operations comprising:
obtaining first data indicative of first overlay error of a substrate;
generating second data indicative of first stress of the substrate based on the first data; and
performing a corrective action based on the second data.

10. The non-transitory machine-readable storage medium of claim 9, wherein the first data comprises a vector map indicating direction and magnitude of overlay error at a plurality of locations of the substrate.

11. The non-transitory machine-readable storage medium of claim 10, wherein generating second data indicative of stress of the substrate comprises performing a divergence calculation based on the vector map.

12. The non-transitory machine-readable storage medium of claim 9, wherein the second data comprises a map of stress values associated with each of a plurality of locations of the substrate.

13. The non-transitory machine-readable storage medium of claim 12, wherein the operations further comprise decomposing the map of stress values into at least a planar portion and a radial portion, and wherein the corrective action is further based on the planar portion or the radial portion.

14. The non-transitory machine-readable storage medium of claim 9, wherein the operations further comprise:
obtaining third data indicative of second overlay error of the substrate; and
generating fourth data indicative of second stress of the substrate based on the third data, wherein the first data and second data are associated with a first substrate film material, and the third and fourth data are associated with a second substrate film material, different than the first.

15. The non-transitory machine-readable storage medium of claim 14, wherein the operations further comprise generating predictive data indicative of stress of a predicted substrate including the first substrate film material and the second substrate film material, wherein generating the predictive data comprises generating a weighted combination of stress maps based on the second data, the third data, and target thicknesses of films of the first substrate film material and the second substrate film material.

16. The non-transitory machine-readable storage medium of claim 9, wherein the corrective action comprises one or more of:
providing an alert to a user;
updating a process recipe; or
recommending a change of components of a substrate processing system.

17. A system, comprising memory and a processing device coupled to the memory, wherein the processing device is configured to:
obtain first data indicative of first overlay error of a substrate;
generate second data indicative of first stress of the substrate based on the first data; and
perform a corrective action based on the second data.

18. The system of claim 17, wherein the first data comprises a vector map indicating direction and magnitude of overlay error at a plurality of locations of the substrate, and wherein generating second data indicative of stress of the substrate comprises performing a divergence calculation based on the vector map.

19. The system of claim 17, wherein the processing device is further configured to:
obtain third data indicative of second overlay error of the substrate; and
generate fourth data indicative of second stress of the substrate based on the third data, wherein the first data and second data are associated with a first substrate film material, and the third and fourth data are associated with a second substrate film material, different than the first.

20. The system of claim 19, wherein the processing device is further to generate predictive data indicative of stress of a predicted substrate including the first substrate film material and the second substrate film material, wherein generating the predictive data comprises generating a weighted combination of stress maps based on the second data, the third data, and target thicknesses of films of the first substrate film material and the second substrate film material.
